(19) United States
(12) Patent Application Publication
(10) Pub. No.: US 2021/0020493 A1
(43) Pub. Date: Jan. 21, 2021

(54) SEMICONDUCTOR MANUFACTURING EQUIPMENT COMPONENT AND METHOD OF MAKING THE SAME

(71) Applicant: NGK SPARK PLUG CO., LTD., Nagoya-shi (JP)

(72) Inventor: Keisuke OOKI, Sendai-shi (JP)

(21) Appl. No.: 16/931,982

(22) Filed: Jul. 17, 2020

(30) Foreign Application Priority Data
Jul. 18, 2019 (JP) 2019-132907
Jul. 8, 2020 (JP) 2020-117614

(51) Int. Cl. H01L 21/687; H01L 21/683

(52) U.S. Cl. CPC H01L 21/68757; H01L 21/6833

(57) ABSTRACT

A semiconductor manufacturing equipment component includes a plate-like aluminum nitride sintered body having a placement surface on which a substrate is to be placed. The aluminum nitride sintered body contains carbon. The aluminum nitride sintered body is formed such that the thermal conductivity of the aluminum nitride sintered body in an in-plane direction is higher than that in a thickness direction. Thus, the semiconductor manufacturing equipment component can prevent heat dissipation in a thickness direction of the aluminum nitride sintered body, and can achieve a uniform temperature distribution as compared with conventional ones.

### CROSS-REFERENCE TO RELATED APPLICATIONS

This application claims priority from Japanese Patent Application No. 2019-132907 filed on Jul. 18, 2019 and Japanese Patent Application No. 2020-117614 filed on Jul. 8, 2020, the entire contents of which are incorporated herein by reference.

### TECHNICAL FIELD

The present disclosure relates to a semiconductor manufacturing equipment component including an aluminum nitride sintered body, and to a method for producing the component.

### BACKGROUND ART

There has been disclosed an aluminum nitride sintered body for a semiconductor manufacturing apparatus, wherein the aluminum nitride sintered body contains carbon fiber and exhibits reduced electrical resistance without deterioration of the characteristics of the sintered body (see, for example, Japanese Patent Application Laid-Open (kokai) No. 2005-41765). The carbon-fiber-containing aluminum nitride sintered body disclosed in Japanese Patent Application Laid-Open (kokai) No. 2005-41765 is produced by a process involving mixing of carbon fiber with aluminum nitride, molding of the resultant powder mixture, and firing of the molded product through heating under vacuum or in an inert or reducing atmosphere. The aluminum nitride sintered body, which contains a small amount of carbon fiber, exhibits reduced electrical resistance through formation of a continuous conductive path by virtue of the carbon fiber having electrical conductivity and a high aspect ratio in fiber shape.

Conventionally, a heater produced by embedding a heater electrode into an aluminum nitride sintered body having high thermal conductivity has been used for uniformly heating a substrate in a film formation step of a semiconductor production process in order to meet the requirement for formation of a film having a uniform thickness.

Although attempts have been made to increase thermal conductivity by using a ceramic material prepared through addition of yttrium oxide to aluminum nitride, a material having higher thermal conductivity has been required, in order to meet the high specifications of semiconductor devices. Therefore, demand has arisen for an aluminum nitride sintered body that achieves a uniform temperature distribution as compared with conventional ones.

### SUMMARY OF INVENTION

In view of the foregoing, objects of the present disclosure are to provide a semiconductor manufacturing equipment component that achieves a uniform temperature distribution as compared with conventional ones, and a method for producing the component.

(1) In order to attain the aforementioned objects, the present disclosure provides a semiconductor manufacturing equipment component comprising a plate-like aluminum nitride sintered body having a placement surface on which a substrate is to be placed, the component being characterized in that:
the aluminum nitride sintered body contains carbon, and
the thermal conductivity of the aluminum nitride sintered body in an in-plane direction along the placement surface is higher than that of the aluminum nitride sintered body in a thickness direction thereof.

According to the present disclosure, the aluminum nitride sintered body is formed such that the thermal conductivity of the aluminum nitride sintered body in an in-plane direction is higher than that in a thickness direction. Thus, the semiconductor manufacturing equipment component, which comprises the aluminum nitride sintered body, can prevent heat dissipation in a thickness direction of the aluminum nitride sintered body, and can achieve a uniform temperature distribution as compared with conventional ones.

(2) In the present disclosure, the carbon may be in the form of graphene, and the graphene may be oriented in an in-plane direction of the aluminum nitride sintered body.

(3) In the present disclosure, an electrode is embedded in the aluminum nitride sintered body.

(4) In the present disclosure, a plurality of electrodes are preferably embedded in the aluminum nitride sintered body such that the electrodes are separated from each other in the thickness direction and overlap each other as viewed in the thickness direction.

(5) In the present disclosure, a tubular support member (e.g., a shaft 3 in an embodiment, the same shall apply hereinafter) is preferably joined to a main surface of the aluminum nitride sintered body opposite the placement surface.

According to the present disclosure, the thermal conductivity in a thickness direction is lower than that in an in-plane direction. Thus, heat is less likely to transfer to the support member, and the aluminum nitride sintered body can maintain a uniform temperature distribution.

(6) The present disclosure also provides a method for producing a semiconductor manufacturing equipment component, the method being characterized by comprising:

a preparing step of preparing a raw material powder by adding graphene to aluminum nitride; and

a sintered body forming step of forming an aluminum nitride sintered body through a pressing step of uniaxially pressing the raw material powder.

According to the method for producing a semiconductor manufacturing equipment component of the present disclosure, the thermal conductivity of an aluminum nitride sintered body in an in-plane direction is made higher than that in a thickness direction by using a raw material powder prepared by adding graphene to aluminum nitride. Thus, the production method can provide a semiconductor manufacturing equipment component including an aluminum nitride sintered body that prevents heat dissipation in a vertical direction of the aluminum nitride sintered body and achieves a uniform temperature distribution as compared with conventional ones.

### BRIEF DESCRIPTION OF DRAWINGS

FIG. 1 is an explanatory view of a semiconductor manufacturing equipment component according to an embodiment of the present invention.

### DESCRIPTION OF EMBODIMENTS

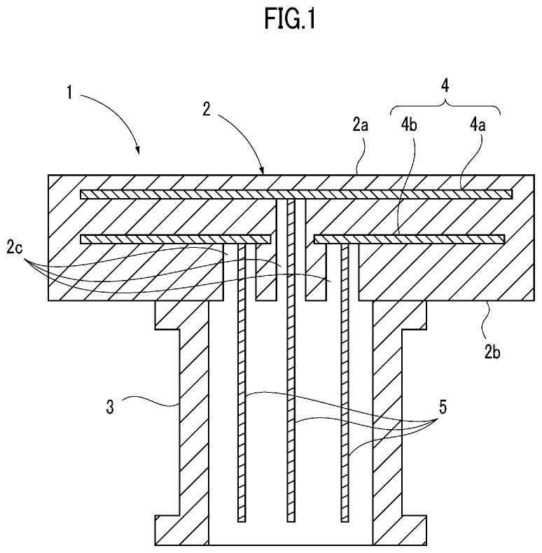

A semiconductor manufacturing equipment component 1 according to an embodiment of the present invention will be described with reference to FIG. 1. The semiconductor manufacturing equipment component 1 of the present embodiment includes an aluminum nitride sintered body 2 having a circular flat plate shape. The semiconductor manufacturing equipment component 1 is used in a semiconductor manufacturing apparatus for placing a substrate (not illustrated) such as a semiconductor wafer on a placement surface 2a of the aluminum nitride sintered body 2 so as to heat the substrate or hold the substrate by electrostatic adsorption. A cylindrical shaft 3 (support member of the present embodiment) is provided on a main surface 2b opposite the placement surface of the circular flat-shape sintered body so as to extend in a thickness direction of the aluminum nitride sintered body 2. Terminals 5 extend in an inner region (hollow portion) of the cylindrical shaft 3 so as to conduct electricity to electrodes 4 embedded in the aluminum nitride sintered body 2. The electrodes 4 include a high-frequency generating electrode 4a and a heater electrode 4b. The high-frequency generating electrode 4a and the heater electrode 4b are embedded in the aluminum nitride sintered body 2 so as to be separated from each other in a thickness direction.

The aluminum nitride sintered body 2 of the embodiment contains graphene serving as a sintering aid and as an additive.

Graphene is composed of a plurality of small sheets of carbon atoms arranged in crystal lattice. Graphene is formed of a small number of stacked carbon sheets, and has a structure wherein the sheets are easily separated in a stacking direction. Thus, graphene is less likely to be distributed three-dimensionally randomly in an aluminum nitride raw material powder. Uniaxial pressing of an aluminum nitride raw material powder containing graphene successfully produced an aluminum nitride sintered body 2 wherein the thermal conductivity in an in-plane direction along the placement surface 2a and main surface 2b of the aluminum nitride sintered body 2 is higher than that in a thickness direction of the aluminum nitride sintered body 2. This is probably attributed to that the graphene contained in the aluminum nitride raw material powder is readily oriented in an in-plane direction of the aluminum nitride through uniaxial pressing in a thickness direction of the aluminum nitride sintered body 2.

In other words, this is probably attributed to that the ratio Ap/Ad is greater than 1 in a cross-sectional image of the aluminum nitride sintered body 2, wherein Ad represents the area of a carbon (graphene) having a length Ld (in a thickness direction of the aluminum nitride sintered body 2) larger than a length Lp (in an in-plane direction of the aluminum nitride sintered body 2), and Ap represents the area of a carbon (graphene) having a length Lp larger than a length Ld. The ratio Ap/Ad is preferably 1.1 or more, more preferably 1.2 or more, still more preferably 1.3 or more.

The aluminum nitride sintered body 2 exhibits a ratio Kp/Kd of more than 1, wherein Kd represents the thermal conductivity of the aluminum nitride sintered body 2 in a thickness direction, and Kp represents the thermal conductivity of the aluminum nitride sintered body 2 in an in-plane direction. The ratio Kp/Kd is preferably 1.1 or more, more preferably 1.2 or more, still more preferably 1.3 or more.

That is, conceivably, when graphene is not oriented in a thickness direction of the aluminum nitride sintered body 2, the thermal conductivity increases in a thickness direction of the aluminum nitride sintered body 2; for example, the amount of heat dissipating from the aluminum nitride sintered body 2, which includes the embedded electrodes 4, to the shaft 3 increases, and a temperature gradient is likely to occur in an in-plane direction of the aluminum nitride sintered body 2, resulting in failure to achieve a uniform temperature distribution.

### [Electrical Conductivity Imparting Effect]

When graphene is added to aluminum nitride before firing, a large portion of the added graphene is probably oriented in an in-plane direction of the resultant aluminum nitride compact; i.e., in an in-plane direction of the sintered body produced by uniaxial pressing and firing (hot pressing). In fact, it was found that the aluminum nitride sintered body 2 exhibits high thermal conductivity in an in-plane direction, and the volume resistivity of the aluminum nitride sintered body in an in-plane direction is slightly lower than that in a thickness direction. Therefore, the aluminum nitride sintered body 2 is provided with electrical conductivity in an in-plane direction, but electrical conductivity is reduced in a thickness direction. Thus, leakage current can be prevented from flowing between the high-frequency generating electrode 4a and the heater electrode 4b that are embedded in the aluminum nitride sintered body 2 so as to be separated in a thickness direction. When the semiconductor manufacturing equipment component 1 is used as an electrostatic chuck produced by embedding an electrostatic adsorption electrode (in place of the high-frequency generating electrode 4a) into the aluminum nitride sintered body 2, the electrostatic chuck can exhibit strong electrostatic adsorption force through the Johnsen-Rahbek effect resulting from electrical conductivity provided through addition of graphene. Consequently, the thermal resistance between the electrostatic chuck and a substrate adsorbed thereon can be reduced, and the substrate can maintain a uniform temperature.

### [Color Tone-Improving Effect]

Graphene uniaxially pressed in aluminum nitride particles are likely to be relatively homogeneously dispersed in the particles, and the resultant aluminum nitride sintered body can exhibit a uniform color tone. Thus, color unevenness can be reduced in a member composed of the aluminum nitride sintered body 2, resulting in a uniform color tone of its appearance. Therefore, the member can exhibit a uniform emissivity even at high temperature.

The graphene to be added is composed of a plurality of sheets of sp2-bound carbon atoms arranged at intervals of about 0.335 nm in aluminum nitride grains in a thickness direction of the aluminum nitride sintered body 2. The number of sheets of sp2-bound carbon atoms was appropriately determined so as to fall within a range of 1 to 50. Graphene particles having a size of 30 μm in an in-plane direction of aluminum nitride particles were used. Thus, the ratio of the in-plane direction size of a graphene particle to the thickness thereof is 1,791 or more.

Yttrium oxide (Y₂O₃) and graphene are added to aluminum nitride.

The raw material is prepared and then uniaxially pressed and fired, to thereby yield an aluminum nitride ceramic material. In the aluminum nitride ceramic material, the additive is oriented in a direction perpendicular to the axis of pressing.

### [Physical Properties of Added Graphene]

Added graphene particles each have a stacking thickness in the thickness direction of 6 nm to 8 nm and a size of 5 μm in an in-plane direction.

The added graphene has a thermal conductivity of 3,000 W/mK in an in-plane direction and a thermal conductivity of 6 W/mK in a direction perpendicular to the in-plane direction.

### [Method for Producing Aluminum Nitride Sintered Body 2]

Firstly, in a preparation step, aluminum nitride raw material powder (140 g) is mixed with graphene (1.6 g), and the mixture is granulated.

Subsequently, in a charging step, the granulated aluminum nitride raw material powder is charged into a cylindrical carbon mold having a diameter of 60 mm.

In a sintered body formation step, the aluminum nitride raw material powder in the carbon mold is subjected to uniaxial pressing and firing (hot pressing) at 1,850° C. and 10 MPa. In the sintered body formation step, uniaxial pressing of the aluminum nitride raw material powder may be performed simultaneously with firing of the raw material powder. Alternatively, firing may be performed after formation of an aluminum nitride compact by uniaxial pressing of the aluminum nitride raw material powder.

After completion of firing, a sample (5 mm×5 mm×5 mm) was cut out of the sintered body for measurement of thermal conductivities in a direction perpendicular to the axis of pressing and in a direction of the axis of pressing (vertical direction). The thermal conductivities were measured by the laser flash method according to JIS R 1611.

### [Results of Measurement of Thermal Conductivity]

As shown in Table 1, the thermal conductivity of an aluminum nitride sintered body 2 containing no graphene (Comparative Example) was measured at 20° C. The aluminum nitride sintered body containing no graphene (Comparative Example) exhibited a thermal conductivity of 170 W/(mK) in both in-plane and thickness directions.

TABLE 1

| | Thermal conductivity [W/(mk)] at 20° C. | |
|---|---|---|
| | In-plane direction | Vertical direction |
| AlN sintered body of | 188.7 | 145.7 |
| the embodiment | | |
| AlN sintered body of | 170 | 170 |
| Comparative Example | | |

In contrast, as shown in Table 1, the graphene-containing aluminum nitride sintered body 2 of the embodiment exhibited thermal conductivities at 20° C. of 188.7 W/(mK) in an in-plane direction and 145.7 W/(mK) in a thickness direction. Thus, the thermal conductivity was lower in a thickness direction and higher in an in-plane direction.

A conceivable reason why the thermal conductivity was lower in a thickness direction of the aluminum nitride sintered body 2 is as follows. Since a large portion of the added graphene, which has a low thermal conductivity in a thickness direction, is oriented in an in-plane direction of the aluminum nitride sintered body 2 by uniaxial pressing, thermal conduction in a thickness direction of the aluminum nitride sintered body 2 is prevented.

As shown in Table 2, other samples were used for measuring the volume resistivities of a graphene-containing aluminum nitride sintered body (Example) and an aluminum nitride sintered body containing no graphene (Comparative Example). The graphene-containing aluminum nitride sintered body (Example) exhibited a volume resistivity of 1.2×10¹³ Ωcm in an in-plane direction at 200° C., whereas the aluminum nitride sintered body containing no graphene (Comparative Example) exhibited a volume resistivity of 3×10¹³ Ωcm in an in-plane direction at 200° C.

The graphene-containing aluminum nitride sintered body exhibited a volume resistivity of 2.7×10¹³ Ωcm in a thickness direction at 200° C.

The volume resistivity can be measured by means of a digital ultra-high resistance/micro current meter manufactured by ADC Corporation.

TABLE 2

| | Volume | Volume |
|---|---|---|
| | resistivity [Ωcm] | resistivity [Ωcm] |
| | 200° C. | 500° C. |
| | In-plane direction | In-plane direction |
| Example | 1.2 × 10¹³ | 5 × 10⁸ |
| Comparative Example | 3 × 10¹³ | 2 × 10⁹ |

The graphene-containing aluminum nitride sintered body (Example) exhibited a volume resistivity of 5×10⁸ Ωcm in an in-plane direction at 500° C., whereas the aluminum nitride sintered body containing no graphene (Comparative Example) exhibited a volume resistivity of 2×10⁹ Ωcm in an in-plane direction at 500° C. The graphene-containing aluminum nitride sintered body exhibited a volume resistivity of 1.6×10⁹ Ωcm in a thickness direction at 500° C.

These results indicate that the aluminum nitride sintered body in which added graphene is oriented in an in-plane direction by uniaxial pressing exhibits a volume resistivity in an in-plane direction lower to some extent than that of the aluminum nitride sintered body containing no graphene of the Comparative Example. A difference is observed between the volume resistivity in an in-plane direction and that in a thickness direction; i.e., the volume resistivity in an in-plane direction is lower than that in a thickness direction. The improvement in electrical conductivity in an in-plane direction is conceivably due to orientation of graphene in an in-plane direction.

Thus, when the aluminum nitride sintered body 2 of the Example is used for a heater at high temperature, the aluminum nitride sintered body can secure electric insulation to some extent. Also, when the aluminum nitride sintered body 2 is used for an electrostatic chuck at high temperature, the volume resistivity of an insulating layer can be reduced as compared with conventional cases, and electrostatic adsorption force can be improved.

Incorporation of graphene leads to a decrease in the volume resistivity of an aluminum nitride sintered body as a whole. However, a decrease in volume resistivity in a thickness direction is reduced as compared with a decrease in volume resistivity in an in-plane direction.

The results indicate that this phenomenon causes an effect of preventing leakage current between two electrodes disposed to overlap in a thickness direction; for example, a high-frequency generating electrode and a heater electrode.

The raw material used in the Example was used to produce an aluminum nitride sintered body 2 including embedded electrodes and containing oriented graphene. A temperature distribution was measured on the sintered body.

Specifically, the aluminum nitride sintered body 2 is produced as follows. An aluminum nitride raw material powder containing graphene is added to a carbon mold. Subsequently, a heater electrode 4b (molybdenum mesh, mesh size: #50, wire diameter: 0.1 mm, plainly woven) is placed on the aluminum nitride powder, and then an aluminum nitride raw material powder is charged into the carbon mold so as to cover the electrode 4b, thereby embedding the electrode 4b in the aluminum nitride powder. The raw material is then subjected to uniaxial pressing and firing. Thereafter, a terminal 5 for connecting the electrode 4b in the aluminum nitride sintered body 2 to an external power source is attached by brazing via an insert hole 2c extending from a main surface 2b of the aluminum nitride sintered body 2 to the electrode 4b.

A heater was set at 500° C. for measurement of a temperature distribution. The temperature distribution of a placement surface 2a was measured by means of an infrared camera after achievement of a steady state. The minimum in-plane temperature was subtracted from the maximum in-plane temperature to thereby determine a ΔT (° C.), and the ΔT was used for evaluation of temperature distribution. The graphene-containing aluminum nitride sintered body 2 of the Example exhibited a ΔT of 10.9° C., whereas the aluminum nitride sintered body 2 containing no graphene exhibited a ΔT of 24.2° C. The results indicate that the graphene-containing aluminum nitride sintered body 2 of the Example exhibits a superior temperature distribution as compared with conventional ones.

The color difference on the surface of the aluminum nitride sintered body 2 was measured at 20 points by means of a color-difference meter, to thereby determine the maximum color difference (Lab color space). As a result, the graphene-containing aluminum nitride sintered body 2 exhibited a color difference of 1.9, whereas the aluminum nitride sintered body 2 containing no graphene exhibited a color difference of 3.8. The results indicate that the graphene-containing aluminum nitride sintered body 2 has a more uniform color tone.

### DESCRIPTION OF REFERENCE NUMERALS

1: Semiconductor manufacturing equipment component

2: Aluminum nitride sintered body

2a: Placement surface

2b: Main surface

2c: Insert hole

3: Shaft (support member)

4: Electrode

5: Terminal

What is claimed is:

1. A semiconductor manufacturing equipment component comprising a plate-like aluminum nitride sintered body having a placement surface on which a substrate is to be placed, wherein
the aluminum nitride sintered body contains carbon, and
the thermal conductivity of the aluminum nitride sintered body in an in-plane direction along the placement surface is higher than that of the aluminum nitride sintered body in a thickness direction thereof.

2. A semiconductor manufacturing equipment component according to claim 1, wherein
the carbon is in the form of graphene, and
the graphene is oriented in the in-plane direction of the aluminum nitride sintered body.

3. A semiconductor manufacturing equipment component according to claim 1, wherein
an electrode is embedded in the aluminum nitride sintered body.

4. A semiconductor manufacturing equipment component according to claim 1, wherein
a plurality of electrodes are embedded in the aluminum nitride sintered body such that the electrodes are separated from each other in the thickness direction and overlap each other as viewed in the thickness direction.

5. A semiconductor manufacturing equipment component according to claim 1 wherein
a tubular support member is joined to a main surface of the aluminum nitride sintered body opposite the placement surface.

6. A method for producing a semiconductor manufacturing equipment component, the component including a plate-like aluminum nitride sintered body having a placement surface on which a substrate is to be placed, the method comprising:
a preparing step of preparing a raw material powder by adding graphene to aluminum nitride; and
a sintered body forming step of forming the aluminum nitride sintered body through a pressing step of uniaxially pressing the raw material powder.
